(19) United States
(12) Patent Application Publication
(10) Pub. No.: US 2011/0204521 A1
(43) Pub. Date: Aug. 25, 2011

(54) CHIP-SCALE SEMICONDUCTOR DEVICE PACKAGE AND METHOD OF MANUFACTURING THE SAME

(75) Inventors: LIANG CHIEH WU, TAIPEI COUNTY (TW); CHENG YI WANG, TAIPEI COUNTY (TW)

(73) Assignee: INPAQ TECHNOLOGY CO., LTD., MIAOLI (TW)

(21) Appl. No.: 13/030,842

(22) Filed: Feb. 18, 2011

(30) Foreign Application Priority Data
Feb. 25, 2010 (TW) 099105411

(51) Int. Cl. H01L 23/48; H01L 21/50

(52) U.S. Cl. 257/769; 257/774; 257/741; 438/125; 438/119; 257/E23.011; 257/E21.499

(57) ABSTRACT

A chip-scale semiconductor device package includes a die, an insulating substrate having a through hole, a first metal layer, a second metal layer, and an insulating layer. The first metal layer is on a first surface of the insulating substrate and a first side of the through hole. The insulating layer is overlaid on a second surface of the insulating substrate and surrounds a second side of the through hole. The second metal is on the insulating layer and the second side of the through hole. The die is in the through hole and includes a first electrode and a second electrode. The first electrode is electrically connected to the first metal layer, and the second electrode is electrically connected to the second metal layer.

### BACKGROUND OF THE INVENTION

1. Field of the Invention

The present invention relates to a semiconductor device package and a manufacturing method thereof, and relates more particularly to a chip-scale semiconductor device package and a method of manufacturing the same.

2. Description of the Related Art

Semiconductor device packages are chips individually enclosed in plastic or ceramic materials. Such semiconductor device packages, called first level packages, require package carriers for supporting and protecting chips, facilitating heat dissipation from chips, and providing passages for input and output of electricity and signals.

The ratio of chip area to package area is a major index for measuring the advancement of a packaging technique; when the index is closer to 1, the packaging technique is more advanced. Several current chip packages are listed below.

(1) Dual in-line packages (DIPs). DIPs, initially developed to package memory chips, are larger than the memory chips packaged therein. DIPs have low packaging efficiency and consume a large installation area.

(2) Thin small outline packages (TSOPs). TSOPs have leads peripherally arranged for surface mounting to trace pads on printed circuit boards. TSOPs are suitable for high-frequency application, can be easily manipulated and have high reliability.

(3) Ball grid array (BGA) packages. The BGA package technique is extensively adopted for packaging very large integrated circuits such as storage devices used in notebooks. Although BGA packages consume more power, BGA packages have improved electrical reliability and heat dissipation characteristics. BGA packages have many advantages: their lead portion pitches can remain unchanged even if more input/output lead portions are added, their production yield is high, they are thin and light, and their signal transmission delay is low so they are suitable for high-frequency application.

(4) Chip scale packages (CSPs). The ratio of chip area to package area of CSPs can be lower than 1:1.5. Compared to BGA packages, CSPs can have smaller size, higher memory volume, and better heat dissipation efficiency. CSPs have good electrical characteristics, highly improved reliability, and high stability. As such, the CSP technique is a best solution for packaging electronic devices such as dynamic random access memory (DRAM) devices.

FIG. 1 is a sectional view showing a conventional semiconductor device package. The conventional semiconductor device package 10 has a substrate 11, a die 12, a plurality of metal wires 13, and an encapsulation body 14. The die 12 is fixed onto the surface of the substrate 11 by adhesive 15 and electrically connects to a plurality of solder pads 112 in the substrate 11 via the plurality of metal wires 13. The substrate 11 has an insulative layer 111. A plurality of conductive pillars 114 are formed through the insulative layer 111 to connect the solder pads 112 with the plural pads 113 on the bottom of the substrate 11. Solder balls (not shown) can be formed on the pads 113 so that the semiconductor device package 10 is turned into a BGA package. To protect the die 12 and the plurality of metal wires 13, the encapsulation body 14 is formed to cover the die 12 and the plurality of metal wires 13 to isolate them from the ambient environment.

To complete a conventional semiconductor device package, complex die bonding, wire bonding, and molding processes are needed. The conventional semiconductor device package also needs a substrate such as a lead frame or a printed circuit board for supporting the die. Consequently, the manufacture cost of the conventional semiconductor device package cannot be effectively lowered. Thus, a new package technique is required so as to circumvent the above drawbacks of a conventional semiconductor device package.

### SUMMARY OF THE INVENTION

The objective of the present invention is to provide a chip-scale semiconductor device package, which can be manufacturing by a simple method. An insulating substrate having a through hole is used as a die carrier. A die is disposed in the through hole and electrically connects a circuit layer on the insulating substrate. Such a chip-scale semiconductor device package can be manufactured with low material cost, and the manufacturing method thereof is greatly simplified so as to improve the production yield and lower the manufacturing cost.

For the above objective, one embodiment of the present invention presents a chip-scale semiconductor device package including a die, an insulating substrate including a through hole, a first metal layer, a second metal layer, and an insulating layer. The first metal layer is formed on the first surface and the first opening The insulating layer is disposed on the second surface of the insulating substrate, surrounding the second opening of the through hole. The second metal layer is disposed on the insulating layer and the second opening The die, including a first electrode and a second electrode, is disposed in the through hole. The first electrode electrically connects the first metal layer, and the second electrode electrically connects the second metal layer.

Another embodiment of the present invention further comprises at least two electrically conductive portions and at least two end electrodes sequentially stacked on two sides of the insulting substrate, being respectively in electrical connection with the first and second metal layers.

In accordance with an embodiment of the present invention, a method of manufacturing a chip-scale semiconductor device package comprises providing an insulating substrate including a first surface, a second surface, and a through hole having a first opening and a second opening; providing a die including a first electrode and a second electrode; disposing the die in the through hole and electrically connecting the first electrode thereof to the first metal layer; forming an insulating layer on the second surface of the insulating substrate; and forming a second metal layer on the insulating layer and the second opening, wherein the second metal layer electrically connects the second electrode.

In one embodiment of the present invention, a conductive portion and an end electrode are sequentially formed on each of two opposite sides of the insulting substrate, wherein the two end electrodes on the opposite sides are respectively in electrical connection with the first and second metal layers.

To better understand the above-described objectives, characteristics and advantages of the present invention, embodiments, with reference to the drawings, are provided for detailed explanations.

### BRIEF DESCRIPTION OF THE DRAWINGS

The invention will be described according to the appended drawings in which:

FIG. 1 is a sectional view showing a conventional semiconductor device package;

FIG. 2 is a view showing a cross section of a chip-scale semiconductor device package according to one embodiment of the present invention; and

FIGS. 3A through 3E are cross-sectional views showing the manufacturing steps of a method of manufacturing a chip-scale semiconductor device package according to one embodiment of the present invention.

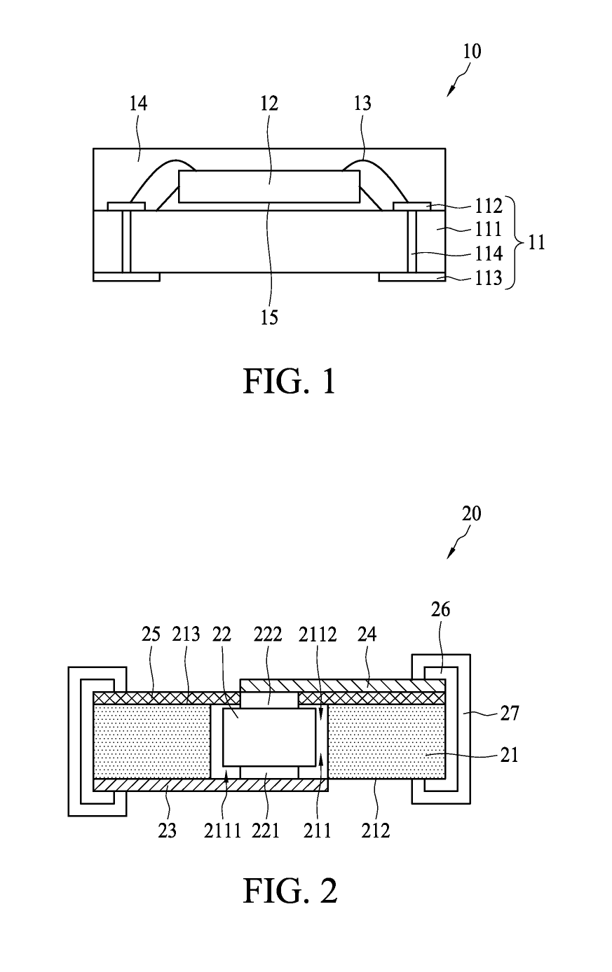

### DETAILED DESCRIPTION OF THE INVENTION

FIG. 2 is a view showing a cross section of a chip-scale semiconductor device package according to one embodiment of the present invention. A chip-scale semiconductor device package 20 comprises a die 22, an insulating substrate 21 including a through hole 211, a first metal layer 23, a second metal layer 24, and an insulating layer 25. The first metal layer 23 is formed on a first surface 212 of the insulating substrate 21 and on a first opening 2111 of the through hole 211. The insulating layer 25 covers a second surface 213 of the insulating substrate 21, surrounding a second opening 2112 of the through hole 211. The second metal layer 24 is formed on the insulating layer 25 and the second opening 2112. The die 22, including a first electrode 221 and a second electrode 222, is disposed in the through hole 211. The first electrode 221 electrically connects to the first metal layer 23, and the second electrode 222 electrically connects to the second metal layer 24.

To allow the chip-scale semiconductor device package 20 to be mountable in a surface-mounting manner, at least two electrically conductive portions 26 and at least two end electrodes 27 are additionally formed in the chip-scale semiconductor device package 20. The at least two electrically conductive portions 26 and the at least two end electrodes 27 are sequentially stacked on two opposite sides of the insulting substrate 21, being respectively in electrical connection with the first and second metal layers 23 and 24.

The first electrode 221, the first metal layer 23, the left side electrically conductive portion 26, and the left side end electrode 27 constitute an electrically conductive path. The second electrode 222, the second metal layer 24, the right side electrically conductive portion 26, and the right side end electrode 27 constitute another electrically conductive path. The left side end electrode 27 and the right side end electrode 27 are configured to be solderable to an external printed circuit board (not shown) to establish electrical connection. As such, the die 22 in the chip-scale semiconductor device package 20 can transmit signals to and from the external printed circuit board.

The insulating substrate 21 can be a substrate of NEMA (National Electrical Manufacturers Association) grade FR-4, aluminum oxide (Al₂O₃), aluminum nitride (AlN), glass, or quartz. Each of the first and second metal layers 23 and 24 may comprise silver (Ag), palladium (Pd), aluminum (Al), chromium (Cr), nickel (Ni), titanium (Ti), gold (Au), copper (Cu), or platinum (Pt). The insulating layer 25 can be made of polyimide, epoxy resin, benzocyclobutene (BCB) polymer, or other suitable polymers.

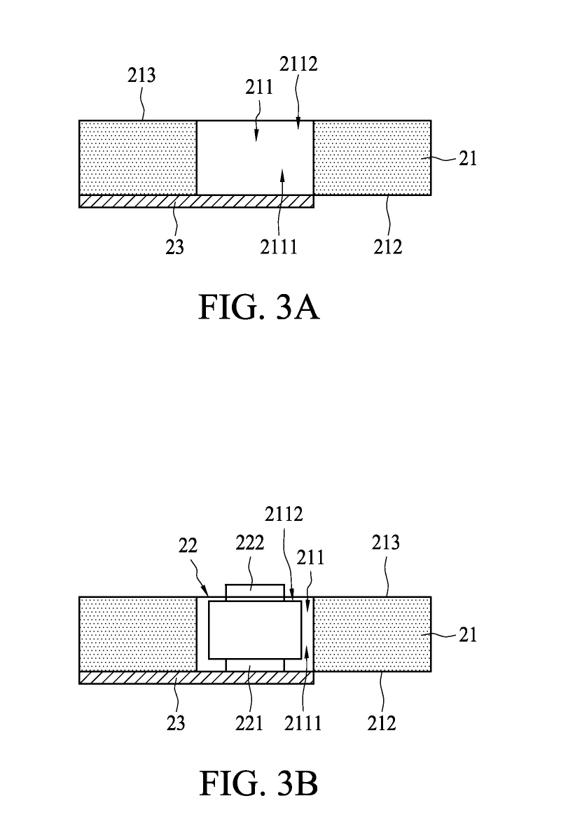

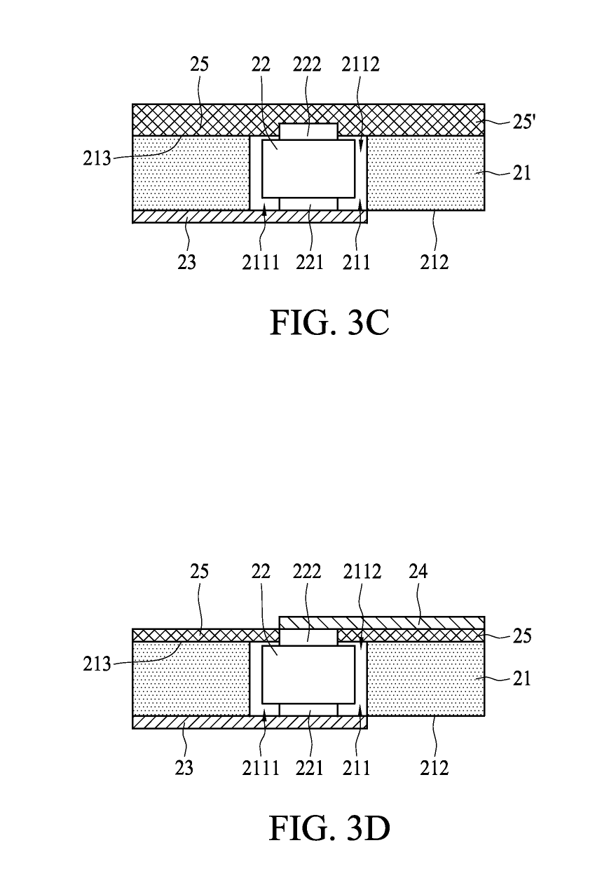

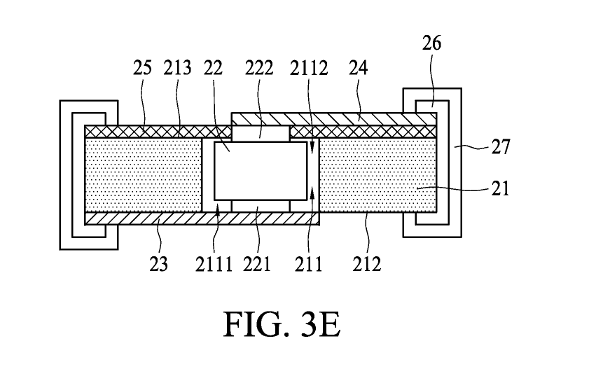

FIGS. 3A through 3E are cross-sectional views showing the manufacturing steps of a method of manufacturing a chip-scale semiconductor device package according to one embodiment of the present invention. As shown in FIG. 3A, an insulating substrate 21 having a through hole 211 and a first surface 212 is provided with a first metal layer 23 formed on the first surface 212 and the first opening 2111 of the through hole 211.

A die 22 having a first electrode 221 and a second electrode 222 is then disposed in the through hole 211 via the second opening 2112 of the through hole 211 with its first electrode 221 electrically connecting the first metal layer 23 as illustrated in FIG. 3B. In one embodiment, electrically conductive adhesive such as silver paste can be applied to the surface of the first metal layer 23 through the second opening 2112 of the through hole 211. After that, the die 22 is assembled with its first electrode 221 bonded with the first metal layer 23 via the electrically conductive adhesive, establishing electrical connection therebetween.

Referring to FIG. 3C, an insulating layer 25′ is formed on a second surface 213 of the insulating substrate 21 and on a second opening 2112 of the through hole 211. A portion of the insulating layer 25′ is removed to expose the second electrode 222. The removal of the portion of the insulating layer 25′ for exposing the second electrode 222 can be processed using a lapping, dry etch, or wet etch process. In one embodiment, the insulating layer 25′ can be filled into the through hole 211.

As shown in FIG. 3D, a second metal layer 24 is formed on the thinned insulating layer 25 and the second opening 2112, electrically connecting the second electrode 222. An electrically conductive portion 26 is then formed on a respective one of two opposite sides of the insulating substrate 21 by a tin or copper dipping process, as shown in FIG. 3E. An end electrode 27 is thereafter formed on the respective electrically conductive portion 26 by a process of electroplating tin and nickel.

The above-described embodiments of the present invention are intended to be illustrative only. Numerous alternative embodiments may be devised by persons skilled in the art without departing from the scope of the following claims.

What is claimed is:

1. A chip-scale semiconductor device package, comprising:
an insulating substrate including a first surface, a second surface, and a through hole formed between the first surface and the second surface, and having a first opening and a second opening;
a first metal layer formed on the first surface and the first opening;
a die including a first electrode electrically connecting the first metal layer and a second electrode, disposed in the through hole;
an insulating layer disposed on the second surface of the insulating substrate, surrounding the second opening of the through hole; and
a second metal layer disposed on the insulating layer and the second opening, electrically connecting the second electrode.

2. The chip-scale semiconductor device package of claim 1, further comprising at least two electrically conductive portions and at least two end electrodes sequentially stacked on two sides of the insulting substrate, being respectively in electrical connection with the first and second metal layers.

3. The chip-scale semiconductor device package of claim 1, further comprising an electrically conductive adhesive disposed between the first electrode and the first metal layer.

4. The chip-scale semiconductor device package of claim 3, wherein the electrically conductive adhesive is silver paste.

5. The chip-scale semiconductor device package of claim 1, wherein the insulating substrate is a substrate of NEMA grade FR-4, aluminum oxide, aluminum nitride, glass, or quartz.

6. The chip-scale semiconductor device package of claim 1, wherein the first metal layer comprises silver, palladium, aluminum, chromium, nickel, titanium, gold, copper, or platinum.

7. The chip-scale semiconductor device package of claim 1, wherein the second metal layer comprises silver, palladium, aluminum, chromium, nickel, titanium, gold, copper, or platinum.

8. The chip-scale semiconductor device package of claim 1, wherein the insulating layer comprises polyimide, epoxy resin, benzocyclobutene polymer, or polymer.

9. The chip-scale semiconductor device package of claim 1, wherein the insulating layer is in the through hole.

10. The chip-scale semiconductor device package of claim 2, wherein the electrically conductive portion comprises silver or copper.

11. The chip-scale semiconductor device package of claim 2, wherein the end electrode comprises tin-nickel alloy.

12. A method of manufacturing a chip-scale semiconductor device package, comprising the steps of:
providing an insulating substrate including a first surface, a second surface, and a through hole having a first opening and a second opening;
providing a die including a first electrode and a second electrode;
forming a first metal layer on the first surface of the insulating substrate and the first opening;
disposing the die in the through hole and electrically connecting the first electrode to the first metal layer;
forming an insulating layer on the second surface of the insulating substrate; and
forming a second metal layer on the insulating layer and the second opening, wherein the second metal layer electrically connects the second electrode.

13. The method of claim 12, further comprising a step of removing a portion of the insulating layer to expose the second electrode.

14. The method of claim 13, wherein the step of removing is performed by a lapping, dry etch, or wet etch process.

15. The method of claim 12, further comprising a step of forming sequentially an electrically conductive portion and an end electrode on a respective one of two sides, wherein the end electrodes are respectively in electrical connection with the first and second metal layers.

16. The method of claim 15, wherein the electrically conductive portions are formed by a tin or copper dipping process.

17. The method of claim 15, wherein the end electrodes are formed by a process of electroplating tin and nickel.

18. The method of claim 12, further comprising a step of disposing an electrically conductive adhesive on the first metal layer for bonding the first electrode.

19. The method of claim 18, wherein the electrically conductive adhesive is silver paste.

20. The method of claim 12, wherein the insulating substrate is a substrate of NEMA grade FR-4, aluminum oxide, aluminum nitride, glass, or quartz.

21. The method of claim 12, wherein the first metal layer comprises silver, palladium, aluminum, chromium, nickel, titanium, gold, copper, or platinum.

22. The method of claim 12, wherein the second metal layer comprises silver, palladium, aluminum, chromium, nickel, titanium, gold, copper, or platinum.

23. The method of claim 12, the insulating layer comprises polyimide, epoxy resin, benzocyclobutene polymer, or polymer.

24. The method of claim 12, wherein the insulating layer is disposed in the through hole.
